(19) United States
(12) Patent Application Publication
(10) Pub. No.: US 2024/0105769 A1
(43) Pub. Date: Mar. 28, 2024

(54) STRUCTURE TO FORM AND INTEGRATE HIGH VOLTAGE FINFET I/O DEVICE WITH NANOSHEET LOGIC DEVICE

(71) Applicant: INTERNATIONAL BUSINESS MACHINES CORPORATION, ARMONK, NY (US)

(72) Inventors: Shahab Siddiqui, Clifton Park, NY (US); Ruqiang Bao, Niskayuna, NY (US); Charlotte DeWan Adams, Schenectady, NY (US); Curtis S. Durfee, Schenectady, NY (US); Anthony I. Chou, Guilderland, NY (US); Barry Paul Linder, Hastings-on-Hudson, NY (US); Ravikumar Ramachandran, Pleasantville, NY (US); Dechao Guo, Niskayuna, NY (US)

(21) Appl. No.: 17/935,992

(22) Filed: Sep. 28, 2022

(51) Int. Cl. H01L 29/06; H01L 21/8234; H01L 29/66; H01L 29/775; H01L 29/78

(52) U.S. Cl. CPC H01L 29/0673; H01L 21/823412; H01L 21/823431; H01L 21/823481; H01L 29/66439; H01L 29/66795; H01L 29/775; H01L 29/7851

(57) ABSTRACT

A semiconductor device includes a substrate having a first region and a second region separated from the first region by distance to define a space therebetween. A first semiconductor device including a gate dielectric is on the first region. The first semiconductor device can implement a FinFet-based input/output (I/O) device in the first region. A second semiconductor device excluding a gate dielectric is on the second region. The second semiconductor device can implement a nanosheet-based logic device in the second region.

### BACKGROUND

The present invention generally relates to fabrication methods and resulting structures for semiconductor devices, and more specifically, to fabrication methods and resulting semiconductor devices integrating a high voltage input/output device with a nanosheet logic device.

Gate-all-around (GAA) field-effect transistors (FETs), such as nanosheet-based transistors (often referred to as nanosheet FETs) provide better electro-static control. Thus, a GAA device architecture helps meet the requirements for further aggressive device scaling. The continued trend to reduce the footprint of FET devices has increased the available area to integrate additional semiconductor devices with a GAA FET on a common semiconductor substrate.

Many circuit designs implement input/output (I/O) devices in devices that utilize logic devices such as logic gates, for example, which do not need to handle the input/output signals directly. Therefore, recent trends in semiconductor device fabrication and design aim to utilize the increased available substrate area provided by reduced FET footprints to integrate a FinFet-based I/O device with a nanosheet-based logic device on a common substrate. These devices that integrate FinFet-based devices and nanosheet-based devices on a common substrate are sometimes referred to as “hybrid transistor devices.”

Traditionally, FinFets that are implanted in I/O devices employ a gate dielectric formed by thermal oxidation of silicon to accommodate for the higher operating voltage of the I/O device, which in some applications may be similar to the external voltage (voltage level of the external/peripheral circuitry). However, the corresponding nanosheet FETs used to implement the logic device on the same substrate oftentimes lacks enough space to grow a dielectric layer. Furthermore, designing the nanosheet FET to provide space that accommodates for dielectric layers when forming the gate dielectric layers of the I/O device FinFets results in the formation of a gate dielectric in the logic nanosheet FET which can degrade the performance of the logic device.

### SUMMARY

Embodiments of the present invention are directed to fabrication methods and resulting semiconductor devices, which implement source/drain placeholder elements that improve epitaxy growth uniformity. According to a non-limiting, embodiment of the invention, a method of fabricating a semiconductor device comprises designating on a substrate a first region and a second region separated from the first region by distance to define a space therebetween. The method further comprises forming a first semiconductor device on the first region and a second semiconductor device on the second region. The first semiconductor device includes a gate dielectric, while the second semiconductor device excludes a gate dielectric. Accordingly, the method facilitates the formation of a semiconductor device that integrates an I/O device capable of handling the higher operating voltage with a nanosheet logic device that avoids performance losses caused by a gate dielectric.

In addition to one or more of the features described herein, or as an alternative, further embodiments of forming the first semiconductor device comprises forming a fin field-effect transistor (FinFET) in the first region, and forming a nanosheet transistor in the second region.

In addition to one or more of the features described herein, or as an alternative, further embodiments of the method comprise forming one or more semiconductor fins in the first region, forming one or more semiconductor nanosheets in the second region, forming an oxide layer on the one or more semiconductor fins and the one or more semiconductor nanosheets, and removing the oxide layer from the one or more semiconductor nanosheets while maintaining the oxide layer on the one or more semiconductor fins to form the gate dielectric.

In addition to one or more of the features described herein, or as an alternative, further embodiments of forming the one or more semiconductor fins comprise forming a bottom dielectric isolation (BDI) layer on an upper surface of the substrate, forming a first nanosheet stack on the BDI layer in the first region, the first nanosheet stack including an alternating arrangement of sacrificial nanosheets and active nanosheets, forming a second nanosheet stack on the BDI layer in the second region, the second nanosheet stack including an alternating arrangement of sacrificial nanosheets and active nanosheets, and replacing the sacrificial nanosheets of the first nanosheet stack with a semiconductor material to form the one or more semiconductor fins, while maintaining the sacrificial nanosheets of the second nanosheet.

In addition to one or more of the features described herein, or as an alternative, further embodiments include depositing a high-k dielectric on the one or more semiconductor fins and the one or more semiconductor nanosheets after removing the dielectric layer from the one or more nanosheets.

In addition to one or more of the features described herein, or as an alternative, further embodiments include forming the dielectric layer such that it is interposed between the one or more semiconductor fins and the high-k dielectric layer.

In addition to one or more of the features described herein, or as an alternative, further embodiments include forming the high-k dielectric layer included in the FinFET directly on the one or more semiconductor fins, and forming the high-k dielectric layer included in the nanosheet transistor directly on the one or more semiconductor nanosheets.

According to another non-limiting embodiment of the invention, a method of fabricating a hybrid transistor device comprises designating on a substrate a first region and a second region separated from the first region by distance to define a space therebetween. The method further comprises forming on the first region a fin field-effect transistors (FinFET) including a gate dielectric, and forming on the second region a nanosheet transistor excluding a gate dielectric. Accordingly, the method forms a hybrid transistor device that integrates an I/O device capable of handling the higher operating voltage with a nanosheet logic device that avoids performance losses caused by gate dielectrics.

In addition to one or more of the features described herein, or as an alternative, further embodiments of the method comprises forming one or more semiconductor fins in the first region, forming one or more semiconductor nanosheets in the second region, forming an oxide layer on the one or more semiconductor fins and the one or more semiconductor nanosheets, and removing the oxide layer from the one or more semiconductor nanosheets while maintaining the oxide layer on the one or more semiconductor fins to form the gate dielectric of the FinFet.

In addition to one or more of the features described herein, or as an alternative, further embodiments of forming the one or more semiconductor fins comprises forming a first nanosheet stack in the first region, the first nanosheet stack including an alternating arrangement of sacrificial nanosheets and active nanosheets, forming a second nanosheet stack in the second region, the second nanosheet stack including an alternating arrangement of sacrificial nanosheets and active nanosheets, and replacing the sacrificial nanosheets of the first nanosheet stack with a semiconductor material to form the one or more semiconductor fins, while maintaining the sacrificial nanosheets of the second nanosheet.

In addition to one or more of the features described herein, or as an alternative, further embodiments of the method comprise forming the active sacrificial nanosheets from a silicon germanium (SiGe) and forming the semiconductor material from silicon (Si) to facilitate formation of a strained heterostructure semiconductor fin, which improves hole mobility through the I/O FinFET. In this manner, performance of the I/O device and logic device can be improved.

In addition to one or more of the features described herein, or as an alternative, further embodiments of the method comprise depositing a high-k dielectric on the one or more semiconductor fins and the one or more semiconductor nanosheets after removing the dielectric layer from the one or more nanosheets.

In addition to one or more of the features described herein, or as an alternative, further embodiments of the method comprise forming the dielectric layer such that it is interposed between the one or more semiconductor fins and the high-k dielectric layer.

In addition to one or more of the features described herein, or as an alternative, further embodiments of the method comprise forming the high-k dielectric layer included in the FinFET directly on the one or more semiconductor fins, and forming the high-k dielectric layer included in the nanosheet transistor directly on the one or more semiconductor nanosheets.

A semiconductor device includes a substrate having a first region and a second region separated from the first region by distance to define a space therebetween. A first semiconductor device including a gate dielectric is on the first region. The first semiconductor device can implement a FinFet-based input/output (I/O) device in the first region. A second semiconductor device excluding a gate dielectric is on the second region. The second semiconductor device can implement a nanosheet-based logic device in the second region. Accordingly, a semiconductor device is provided which integrates an I/O device capable of handling the higher operating voltage with a nanosheet logic device that avoids performance losses caused by a gate dielectric.

In addition to one or more of the features described herein, or as an alternative, further embodiments of the semiconductor device include an input/output (I/O) device on the first region and including the first semiconductor device, and a logic device on the second region and including the second semiconductor device.

In addition to one or more of the features described herein, or as an alternative, further embodiments of the semiconductor device provides the first semiconductor device as a fin field-effect transistor (FinFET) including one or more semiconductor fins, and the second semiconductor device as a nanosheet transistor including one or more semiconductor nanosheets.

In addition to one or more of the features described herein, or as an alternative, further embodiments of the semiconductor device include a first high-k dielectric layer formed directly on the gate dielectric such that the gate dielectric is interposed between the first high-k dielectric layer and the one or more semiconductor fins, and a second high-k dielectric layer formed directly on the one or more semiconductor nanosheets.

In addition to one or more of the features described herein, or as an alternative, further embodiments of the semiconductor device provide a logic device that includes a semiconductor material defining a fin body extending continuously from an upper surface of the semiconductor fin to a base formed on an upper surface of the substrate.

In addition to one or more of the features described herein, or as an alternative, further embodiments of the semiconductor device provide a logic device including a semiconductor fin with alternating layers of silicon germanium (SiGe) and silicon (Si). The alternating layers extend continuously from an upper surface of the semiconductor fin to a base formed on an upper surface of the substrate.

Other embodiments of the present invention implement features of the above-described devices/structures in methods and/or implement features of the methods in devices/structures. Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings presented herein.

FIGS. 1-14 depict a series of views illustrating a method of forming a semiconductor device according to exemplary embodiments of the present teachings, in which:

FIG. 1. illustrates a starting semiconductor structure for forming a hybrid semiconductor device according to a non-limiting embodiment of the invention;

FIG. 2 illustrates the starting semiconductor structure following one or more semiconductor fabrication processes according to one or more non-limiting embodiments;

FIG. 3 illustrates the starting semiconductor structure following one or more semiconductor fabrication processes according to one or more non-limiting embodiments;

FIG. 4 illustrates the starting semiconductor structure following one or more semiconductor fabrication processes according to one or more non-limiting embodiments;

FIG. 5 illustrates the starting semiconductor structure following one or more semiconductor fabrication processes according to one or more non-limiting embodiments;

FIG. 6 illustrates the starting semiconductor structure following one or more semiconductor fabrication processes according to one or more non-limiting embodiments;

FIG. 7 illustrates the starting semiconductor structure following one or more semiconductor fabrication processes according to one or more non-limiting embodiments;

FIG. 8 illustrates the starting semiconductor structure following one or more semiconductor fabrication processes according to one or more non-limiting embodiments;

FIG. 9 illustrates the starting semiconductor structure following one or more semiconductor fabrication processes according to one or more non-limiting embodiments;

FIG. 10 illustrates the starting semiconductor structure following one or more semiconductor fabrication processes according to one or more non-limiting embodiments;

FIG. 11 illustrates the starting semiconductor structure following one or more semiconductor fabrication processes according to one or more non-limiting embodiments;

FIG. 12 illustrates the starting semiconductor structure following one or more semiconductor fabrication processes according to one or more non-limiting embodiments;

FIG. 13 illustrates the starting semiconductor structure following one or more semiconductor fabrication processes according to one or more non-limiting embodiments;

FIG. 14 illustrates the starting semiconductor structure following one or more semiconductor fabrication processes according to one or more non-limiting embodiments;

FIG. 15 illustrates the starting semiconductor structure following one or more semiconductor fabrication processes according to one or more non-limiting embodiments;

FIG. 16 illustrates the starting semiconductor structure following one or more semiconductor fabrication processes according to one or more non-limiting embodiments; and

FIG. 17 illustrates the starting semiconductor structure following one or more semiconductor fabrication processes according to one or more non-limiting embodiments.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details. For example, a description of a substrate and/or a semiconductor device to form various features (e.g., cavities, openings, trenches, holes, etc.) following various lithography and patterning operations can include various well-known deposition, lithography, photoresist, and etchings processes and techniques.

As explained above, nanosheet FETs used to implement the logic device on the same substrate oftentimes lacks enough space to grow a dielectric layer. Furthermore, designing the nanosheet FET to provide space that accommodates for dielectric layers when forming the gate dielectric layers of the I/O device FinFets results in the formation of a gate dielectric in the logic nanosheet FET which can degrade the performance of the logic device. One or more non-limiting embodiments of the invention solve the shortcomings of conventional hybrid transistor devices by providing a semiconductor device (e.g., a hybrid transistor device) that includes one or more FinFet-based devices implementing gate dielectrics and one or more nanosheet-based devices omitting gate dielectrics. In this manner, a hybrid transistor device is provided that integrates an I/O device capable of handling the higher operating voltage with a nanosheet logic device that avoids performance losses caused by gate dielectrics.

With reference now to FIG. 1 illustrates, a semiconductor structure 100 serving as a starting point for fabricating a hybrid transistor device is shown according to a non-limiting embodiment of the present invention. The semiconductor structure 100 includes a semiconductor substrate 102 having a first region 104 and a second region 106 located a distance away from the first region 104. The first region 104 is designated to support a first semiconductor device, while the second region 106 is designated to support a second semiconductor device. According to one or more non-limiting embodiments, the first region 104 is designate to support an input/output (I/O) device, while the second region 106 is designated to support a logic device. According to one or more non-limiting embodiments of the invention, an I/O devices can be referred to as devices that handle the input and/or output voltages/currents, and as such need to be able to tolerate a greater amount of voltage or current swing than the logic device. In some non-limiting embodiments of the invention, the logic device includes core devices that do not need to handle the input/output voltages/currents directly. For example, the logic device can include various logic gates such as NAND, NOR, INVERTER, etc. In some embodiments, the core devices can include an SRAM (static random-access memory) region. It should be appreciated that the first region 104 and the second region 106 may each support other types of semiconductor device without departing from the scope of the invention.

With continued reference to FIG. 1, the semiconductor structure 100 further includes a first semiconductor stack 108 and a second semiconductor stack 109. The first semiconductor stack 108 is formed on an upper surface of the substrate 102 in the first region 104, while the second semiconductor stack 109 is formed on the upper surface of the substrate in the second region 106. Each of the first and second semiconductor stacks 108 and 109 can have a length (e.g., along the X-axis direction) ranging, for example, from about 35 nanometers (nm) to about 45 nm. In one or more non-limiting embodiments, a bottom dielectric isolation (BDI) layer (not shown in FIG. 1) can be formed between the substrate 102 and the first and second semiconductor stacks 108 and 109. The BDI layer can improve the sub-threshold characteristics and increase the process and electrical stability of the NSFET devices formed on the substrate 102. The BDI layer can also provide improved immunity of sub-channel leakage due to process variation produced by parasitic “fat-Fins” or “wide-Fins”, which are unique in nanosheet structures.

A space 101 or void 101 is between first semiconductor stack 108 and the semiconductor stack 109 due to the distance between the first region 104 and the second region 106. The space 101 or void 101 allows performing various fabrications processes (e.g., patterning, etching, deposition, etc.) on one of the semiconductor stacks without processes or damaging the other semiconductor stack. For example, one or more fabrication processes can be performed in the first region 104 to pattern, etch, deposit materials, etc. on the first semiconductor stack 108 without extending the fabrications processes into the second region 106 to process or damage the second semiconductor stack 109, and vice versa.

The first semiconductor stack 108 includes an alternating stack of sacrificial nanosheets 110 and active nanosheets 112. The sacrificial nanosheets 110 can be formed from a first semiconductor material, while the active nanosheets 112 can be formed from a second semiconductor material different from the first semiconductor material. According to one or more non-limiting embodiments of the invention, the sacrificial nanosheets 110 are formed from silicon germanium (SiGe), while the active nanosheets 112 are formed from silicon (Si). According to a non-limiting embodiment of the invention, the lowest-stacked sacrificial nanosheet 110 included in the first semiconductor stack 108 is formed on the upper surface of the semiconductor substrate 102 in the first region 104. Accordingly, the lowest-stacked active nanosheet 110 included in the first semiconductor stack 108 is formed on the upper surface of the lowest-stacked sacrificial nanosheet 110.

Likewise, the second semiconductor stack 109 includes an alternating stack of sacrificial nanosheets 111 and active nanosheets 113. The sacrificial nanosheets 111 can be formed from a first semiconductor material, while the active nanosheets 113 can be formed from a second semiconductor material different from the first semiconductor material. According to one or more non-limiting embodiments of the invention, the sacrificial nanosheets 111 are formed from silicon germanium (SiGe), while the active nanosheets 113 are formed from silicon (Si). The thickness (e.g., in the Z-axis direction) of the sacrificial nanosheets 110 can range, for example, from about 7 nm to about 11 nm, and the thickness of the active nanosheets 112 can range, for example, from about 8 nanometers (nm) to about 12 nm. In one or more non-limiting embodiments of the invention, the lowest-stacked sacrificial nanosheet 111 included in the second semiconductor stack 109 is formed on the upper surface of the semiconductor substrate 102 in the second region 106. Accordingly, the lowest-stacked active nanosheet 113 included in the second semiconductor stack 109 is formed on the upper surface of the lowest-stacked sacrificial nanosheet 111.

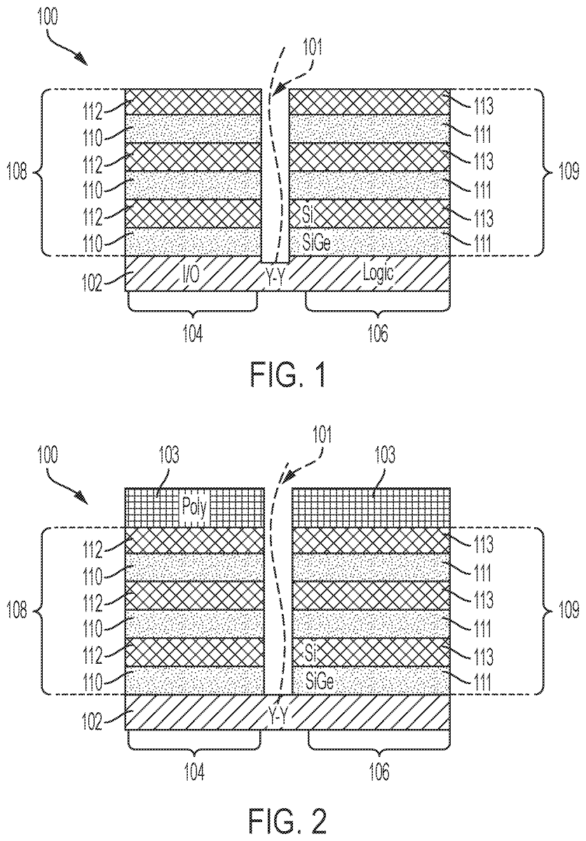

Turning now to FIG. 2, the semiconductor structure 100 is illustrated after depositing a masking layer 103 on upper surface of the first semiconductor stack 108 and the second semiconductor stack 109. According to one or more non-limiting embodiments, the masking layer 103 is formed from various masking materials including, but not limited to, a polysilicon material, silicon oxide (SiO), and silicon nitride (SiN). Accordingly, the masking layer 103 can serve as a hardmask when performing various semiconductor fabrication and patterning processes described herein.

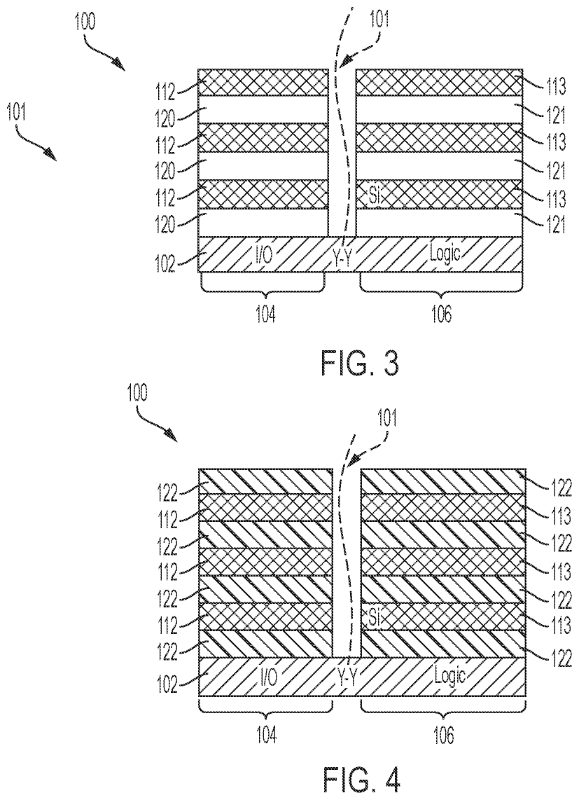

Referring to FIG. 3, the semiconductor structure 100 is illustrated after selectively removing the sacrificial nanosheets 110 and 111 with respect to the active nanosheets 112 and 113. In one or more non-limiting embodiments of the invention, a wet etch or dry etch process having an etchant chemistry chosen to attack the material of the sacrificial nanosheets 110 and 111 (e.g., SiGe) without attacking, or substantially attaching, the active nanosheets 112 and 113 (e.g. Si) can be performed to selectively remove the sacrificial nanosheets 110 and 111. In this manner, the active nanosheets 112 and 113 can be “released” to form voids 120 and 121 between the active nanosheets 112 and 113. The released active nanosheets 112 and 113 can serve as channels (e.g., N-channels or P-channels) of a respective semiconductor device as described herein.

With reference to FIG. 4, the semiconductor structure 100 is illustrated after filling the voids 120 and 121 located with a sacrificial material 122. According to one or more non-limiting embodiments, the sacrificial material 122 can be formed from a dielectric material including, but not limited to polysilicon, silicon oxide (SiO), and silicon nitride (SiN). Although not illustrated, a masking layer can be deposited on an upper surface of the sacrificial material to expose the first region 104, while covering the second region 106.

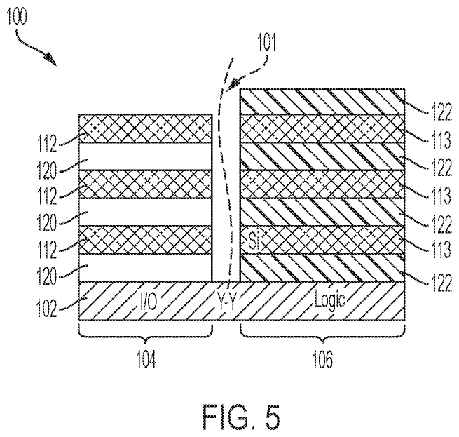

Turning now to FIG. 5, the semiconductor structure 100 is illustrated after selectively removing the sacrificial material 122 located in the first region 104, while maintaining the sacrificial material 122 and the active nanosheets 113 located in the second region 106. According to one or more non-limiting embodiments of the invention, an etching process employs an etchant chemistry that attacks the material of the sacrificial material 122 without attacking the material of the active nanosheets 112. In this manner, the sacrificial material 122 can be selectively removed with respect to the active nanosheets 112 to form voids 120 between the active nanosheets 112. As described herein, the active nanosheets 113 located in the second region 106 can avoid removal due to the space 101 separating them from the first region 104 and/or the masking layer maintained in the second region 106.

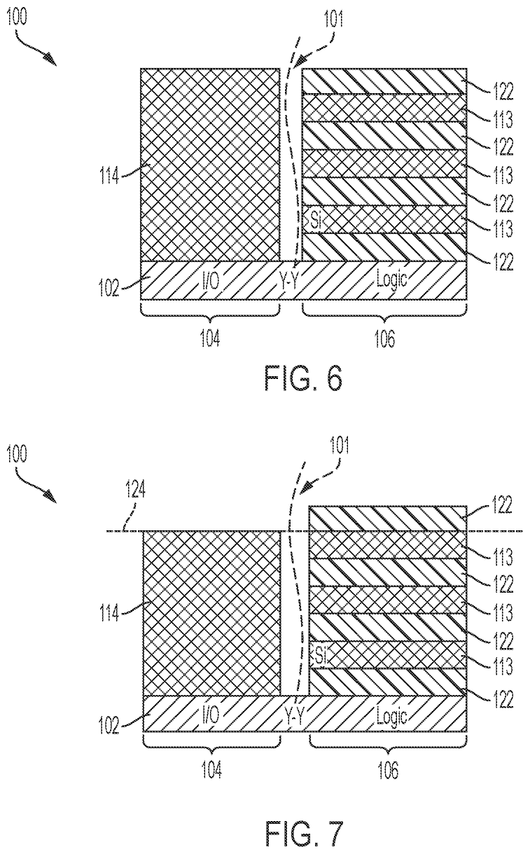

Referring to FIG. 6, the semiconductor structure 100 is illustrated after performing an epitaxy process in the first region 104. The epitaxy process involves growing an epitaxial material from surfaces of a semiconductor material that are exposed to gaseous or liquid precursors. The space 101 separating the second region 106 from the first region 104 and/or the dielectric sacrificial material 123 prevents epitaxy growth on the active nanosheets 113 located in the second region 106.

According to one or more non-limiting embodiments of the invention, the epitaxy process can employ vapor-phase epitaxy (VPE), molecular-beam epitaxy (MBE), liquid-phase epitaxy (LPE), or other suitable process to promote epitaxy material growth. Epitaxial silicon, silicon germanium, and/or carbon doped silicon (Si:C) silicon, for example, can be doped during deposition (in-situ doped) by adding dopants, n-type dopants (e.g., phosphorus or arsenic) or p-type dopants (e.g., boron or gallium), depending on the type of transistor.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a {100} orientated crystalline surface will take on a {100} orientation. In some embodiments of the invention, epitaxial growth and/or deposition processes are selective to forming on semiconductor surfaces, and generally do not deposit material on non-crystalline surfaces such as silicon dioxide or silicon nitride.

In some embodiments of the invention, the gas source for the deposition of epitaxial semiconductor material includes a silicon containing gas source, a germanium containing gas source, or a combination thereof. For example, an epitaxial Si layer can be deposited from a silicon gas source that is selected from the group consisting of silane, disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane and combinations thereof. An epitaxial germanium layer can be deposited from a germanium gas source that is selected from the group consisting of germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, nitrogen, helium and argon can be used.

With continued reference to FIG. 6, the epitaxy process can be continued until the voids 120 are filled to form an integral, fully solid semiconductor “fin” 114. For example, the semiconductor fin 114 comprises a semiconductor material defining a fin body extending continuously from an upper surface of the semiconductor fin to a base formed on an upper surface of the semiconductor substrate 102. In one or non-limiting embodiments, the fin body is formed entirely of the single semiconductor material such as, for example, silicon (Si). Accordingly, the semiconductor fin 114 can extend from a fin base formed on the upper surface of the substrate 102 to an opposing upper fin surface. Although a single semiconductor fin 114 is illustrated, it should be appreciated that additional semiconductor fins 114 (e.g., two, three, etc.) can be included in the semiconductor device 100 (e.g., in the first region 104) to be used with the logic device.

In one or more non-limiting embodiments of the invention, the upper fin surface is aligned with or extends above the upper surface of the sacrificial material 122 located in the second region 106. In this scenario, a portion of the semiconductor material can be recessed such that its height is aligned or substantially aligned with the upper surface of the upper-most active nanosheet 102 (indicated by the dashed lined 124), as shown in FIG. 7. According to one or more non-limiting embodiments, reactive ion etch (RIE) process or a chemical-mechanical planarization (CMP) process can be performed to recess the height of the semiconductor fin 114.

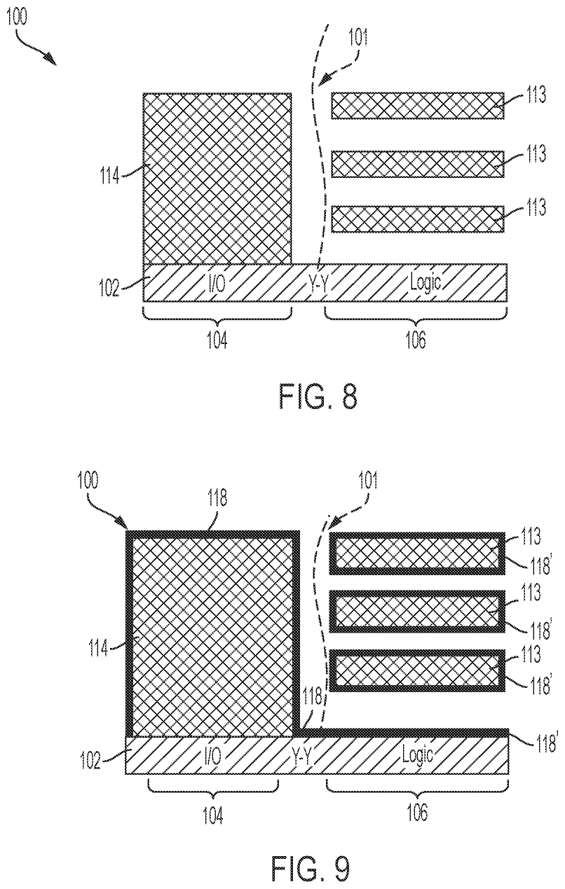

Turning to FIG. 8, the semiconductor structure 100 is illustrated after selectively removing the sacrificial material 122 with respect to the active nanosheets 113. In one or more non-limiting embodiments of the invention, a wet etch or dry etch process can be performed to selectively remove the sacrificial material 122. The etching process employs an etchant chemistry chosen to attack the sacrificial material without attacking, or substantially attaching, the active nanosheets 113. The released active nanosheets 113 can serve as channels (e.g., N-channels or P-channels) of a nanosheet semiconductor device formed in the second region 106 as described herein.

With reference to FIG. 9, the semiconductor device 100 is illustrated following deposition of an oxide layer 118/118′ in the first region 104 and the second region 106. The oxide layer 118/118′ can be deposited using various deposition processes including, but not limited to, atomic layer deposition (ALD) and plasma enhanced ALD (PEALD). Accordingly, the oxide layer 118/118′ can conform to the exposed surfaces of the semiconductor fin 114, exposed surfaces of the active nanosheets 113, and exposed surfaces of the semiconductor substrate 102. The oxide layer 118/118′ can be formed from various oxide materials including, but not limited to, SiO2, and can be deposited in the first and second regions 104 and 106 using a single deposition process or separate deposition processes.

According to one or more non-limiting embodiments, the thickness of oxide layer 118/118′ can be selected based at least in part on a target thickness of a gate dielectric to be formed on the semiconductor fin 114. For example, a thickness of the oxide layer 118/118′ can range, for example, from about 2 nm to about 5 nm.

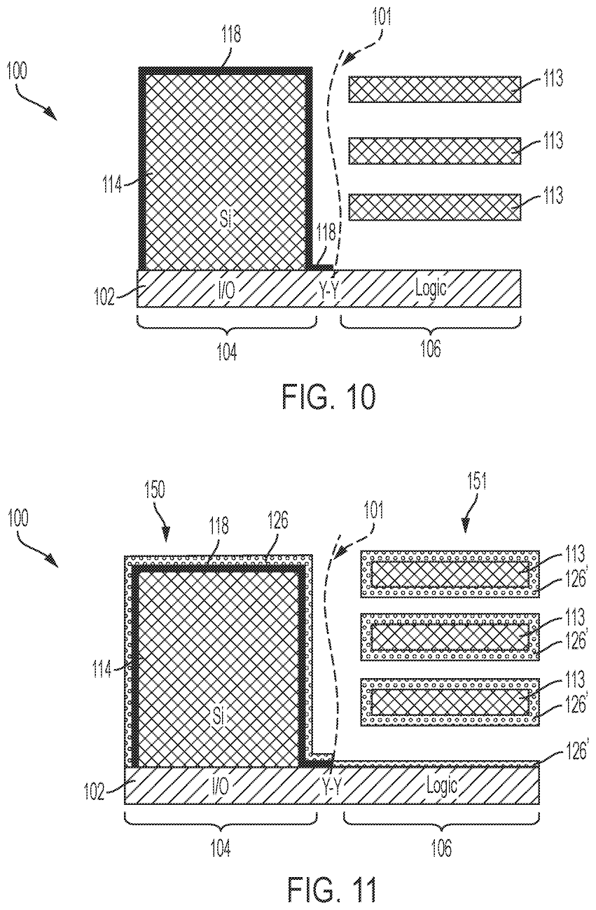

Referring to FIG. 10, the semiconductor device is illustrated after selectively removing the oxide layer 118′ from the nanosheets 113 located in the second region 106, while maintaining the oxide layer 118 on the semiconductor fin 114 located in the first region 104. According to one or more non-limiting embodiments of the invention, an etching process employs an etchant chemistry that attacks the material of the oxide layer 118′ without attacking the material of the underlying active nanosheets 112. As described herein, the oxide layer 118 located in the first region 104 can avoid removal due to the space 101 separating it from the second region 106 and/or due to a masking layer (not shown in FIG. 10) that covers the semiconductor fin 114.

As described herein, the remaining gate oxide layer 118 formed on the semiconductor fin 114 can serve as a gate dielectric 118 for a corresponding semiconductor device (e.g., an I/O device) according to one or more non-limiting embodiments of the invention. Therefore, unlike conventional hybrid transistor devices, the semiconductor FinFet 114 formed in the first region 104 designated to support a first semiconductor device (e.g., an I/O device) can include an oxide layer 118 (e.g., a gate dielectric), while a second semiconductor device (e.g., a nanosheet-based logic device) formed in the second region 106 designated to support a second semiconductor device (e.g., an I/O device) can exclude the gate oxide 118 (e.g., a gate dielectric). Not only does removing the oxide layer 118′ allow for improving the performance of a completed logic device formed in the second region 106, but allows for increasing the thickness of the oxide layer 118 to be used as the gate dielectric of the FinFet 114 implementing the I/O device formed in the first region 104 without the need to consider spacing limitations associated with nanosheets 113 to be used to form the nanosheet-based logic device in the second region. Accordingly, the I/O device can be formed with a thicker gate dielectric 118 compared to conventional hybrid transistor device that integrate and I/O device and nanosheet-based logic device on a common substrate.

Referring to FIG. 11, the semiconductor device 100 is illustrated following deposition of a high-k dielectric layer 126/126′ in the first region 104 and the second region 106. The high-k dielectric layer 126/126′ can be deposited using various deposition processes including, but not limited to, atomic layer deposition (ALD) and plasma enhanced ALD (PEALD). Accordingly, the high-k dielectric layer 126/126′ can conform to the exposed surfaces of the oxide layer 118 (i.e., the gate dielectric 118), exposed surfaces of the active nanosheets 113, and exposed surfaces of the semiconductor substrate 102. The high-k dielectric layer 126/126′ can be formed from various high-k dielectric materials (e.g. material with a greater dielectric constant (K) compared to SiO2) and can be deposited in the first and second regions 104 and 106 using a single deposition process or separate deposition processes. In one or more non-limiting embodiments, the high-k dielectric material includes, but is not limited to, hafnium silicate (HfSiO4), zirconium silicate (ZrSiO4), hafnium dioxide (HfO2), and zirconium dioxide (ZrO2).

As described herein, various non-limiting embodiments of the invention described herein provide a process flow that fabricates a semiconductor device 100 (e.g., a hybrid transistor device) illustrated in FIG. 11, which includes a fin field-effect transistor (FinFet) 150 for implementing an I/O device with a common source/drain, along with an integrated a nanosheet transistor 151 for implementing a logic device. The resulting semiconductor device 100 allows the I/O device to operate at increased voltages (e.g., about 1.2 V to about 3.5 V), while omitting formation of a gate dielectric on the nanosheets that can lead to a degraded performance of the logic device.

According to one or more non-limiting embodiments of the invention, the process flow described herein can be utilized to introduce strain in the FinFet 114 of the logic device. The strained FinFET 114 provides a hybrid architecture, which provides a strained heterostructure FinFet that promotes hole mobility therethrough and improves the operating performance of the corresponding I/O device and logic device.

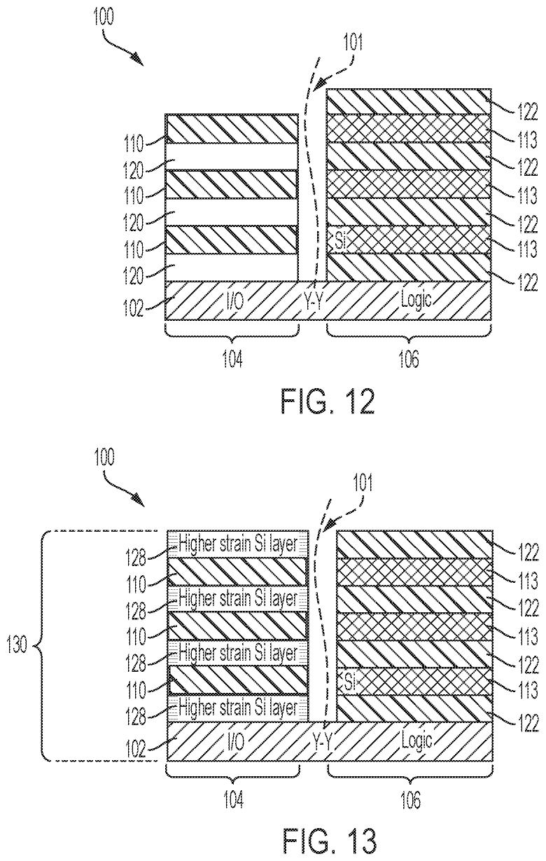

FIG. 12, for example, illustrates the semiconductor structure 100 after selectively removing sacrificial Si nanosheets located in the first region 104 to release SiGe nanosheets 110, while maintaining the sacrificial material 122 and the active nanosheets 113 located in the second region 106 (similar processes as used in FIG. 5 can be performed to achieve the semiconductor substrate 100 shown in FIG. 12). Accordingly, voids 120 expose the surfaces of the SiGe nanosheets 110.

Turning to FIG. 13, the semiconductor device 100 is illustrated following an epitaxy process that grows a Si material 128 from the exposed surfaces of the SiGe nanosheets 110. Accordingly, the SiGe nanosheets 110 induce a strain on the epitaxy Si material 128, thereby producing a strained heterostructure FinFet 130 having one or more high-strain Si layers 128 that promote hole mobility therethrough.

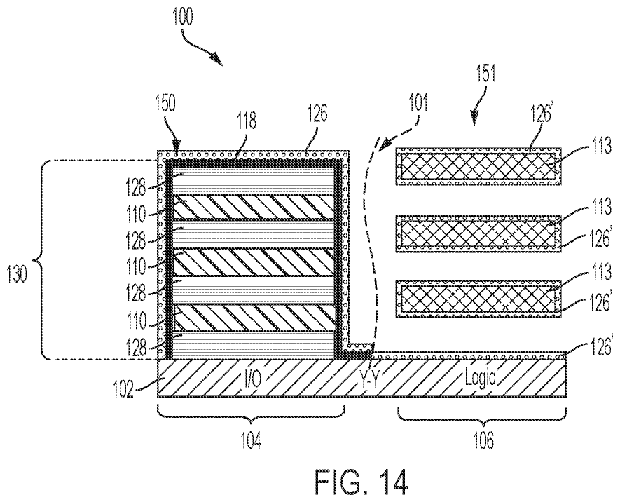

At FIG. 14, the semiconductor device 100 is illustrated after completing the various fabrication process illustrated in FIGS. 6-11 to provide a semiconductor device 100 (e.g., a hybrid transistor device) that integrates a strained heterostructure semiconductor fin 130 for implementing a FinFet 150 included in an I/O device having a gate dielectric with a nanosheet transistor 151 for implementing a logic device that excludes a gate dielectric. Although a single strained heterostructure semiconductor fin 130 is illustrated, it should be appreciated that additional strained heterostructure semiconductor fins 130 can be included in the semiconductor device 100 (e.g., in the first region 104) to be used with the logic device without departing from the scope of the invention.

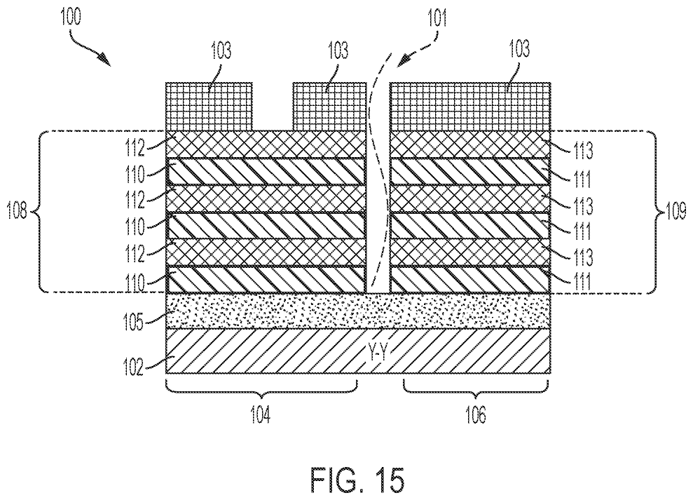

As described herein, the semiconductor device 100 can also include additional semiconductor fins 114 (e.g., in the first region 104) to be used with the logic device, along with a BDI layer formed between the substrate 102 and the I/O device 150 and/or the logic device 151. Turning to FIG. 15, for example, a semiconductor structure 100 used to form multiple semiconductor fins in the I/O region 104 is illustrated according to a non-limiting embodiment. The semiconductor structure 100 includes a BDI layer 105 interposed between the semiconductor substrate 102, a first semiconductor stack 108 (e.g., an I/O semiconductor stack 108) and a second semiconductor stack 109 (e.g., a logic semiconductor stack 109). The BDI layer 105 can be formed from any dielectric material including, for example, an oxide material or a nitride material.

With continued reference to FIG. 15, the patterned masking layer 103 is formed on upper surface of the first semiconductor stack 108 and the second semiconductor stack 109. In this example, the masking layer 103 is patterned in a manner to form multiple semiconductor fins in the I/O region 104 as described herein.

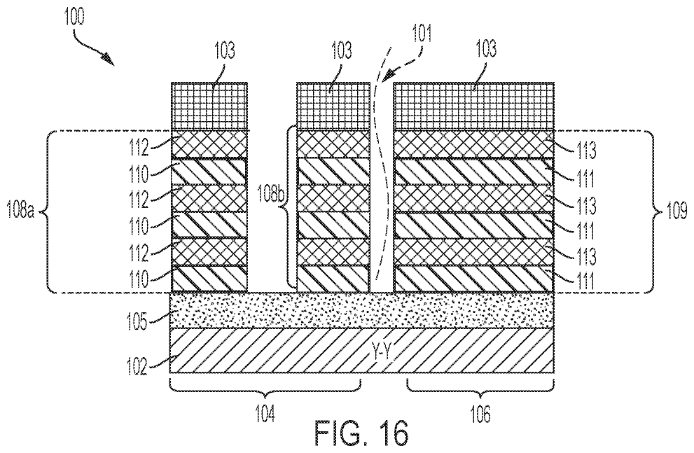

Turning to FIG. 16, the semiconductor structure 100 is illustrated after transferring the masking pattern defined by the masking layer 103 into the first semiconductor stack 108. Accordingly, a plurality of individual I/O semiconductor stacks 108a and 108b are formed on an upper surface of the BDI layer 105 located in the I/O region 104.

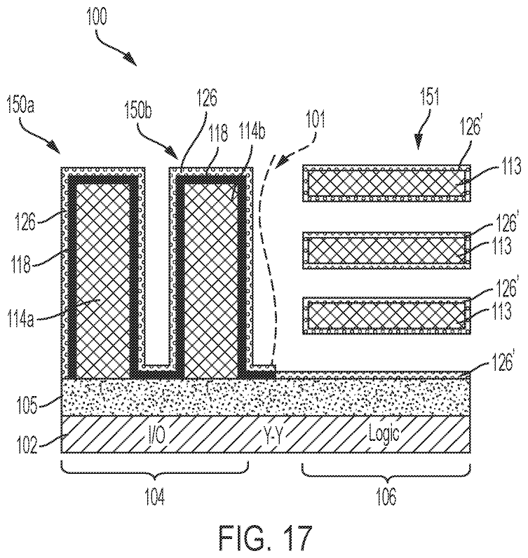

Following the formation of the individual I/O semiconductor stacks 108 and 108, various fabrication operations according to the process flow described herein can be performed to form multiple FinFets 150a and 150b as illustrated in FIG. 17. Accordingly, multiple FinFets 150a and 150b including a gate oxide layer 118 (e.g., a gate dielectric 118) can be implementing an I/O device with a common source/drain, along with an integrated a nanosheet transistor 151 that excludes a gate dielectric for implementing a logic device formed on a common substrate 102.

As described herein, various non-limiting embodiments of the invention provide a semiconductor device (e.g., a hybrid transistor device) that includes one or more FinFet-based devices implementing gate dielectrics and one or more nanosheet-based devices omitting gate dielectrics. In this manner, a semiconductor device is provided that integrates an I/O device capable of handling the higher operating voltage with a nanosheet logic device that avoids performance losses caused by gate dielectrics

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. Accordingly, in the interest of brevity, many conventional implementation details are only mentioned briefly herein or are omitted entirely without providing the well-known system and/or process details. For example, a description of patterning a substrate to form various features (e.g., cavities, openings, trenches, holes, etc.) can include the deposition, lithography, photoresist, and etchings processes and techniques described above. Therefore, reference to a patterned substrate and/or patterned semiconductor device at one or more stages of the process flow may omit full details of the deposition, lithography, photoresist, and/or etchings processes and techniques described above for the sake of brevity.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method of fabricating a semiconductor device, the method comprising:
designating on a substrate a first region and a second region separated from the first region by distance to define a space therebetween;
forming a first semiconductor device on the first region, the first semiconductor device including a gate dielectric; and
forming a second semiconductor device on the second region, the second semiconductor device excluding a gate dielectric.

2. The method of claim 1, wherein forming the first semiconductor device comprises forming a fin field-effect transistor (FinFET) in the first region and forming a nanosheet transistor in the second region.

3. The method of claim 2, further comprising:
forming one or more semiconductor fins in the first region;
forming one or more semiconductor nanosheets in the second region;
forming an oxide layer on the one or more semiconductor fins and the one or more semiconductor nanosheets; and
removing the oxide layer from the one or more semiconductor nanosheets while maintaining the oxide layer on the one or more semiconductor fins to form the gate dielectric.

4. The method of claim 3, wherein forming the one or more semiconductor fins comprises:
forming a bottom dielectric isolation (BDI) layer on an upper surface of the substrate;
forming a first nanosheet stack on the BDI layer in the first region, the first nanosheet stack including an alternating arrangement of sacrificial nanosheets and active nanosheets;
forming a second nanosheet stack on the BDI layer in the second region, the second nanosheet stack including an alternating arrangement of sacrificial nanosheets and active nanosheets; and
replacing the sacrificial nanosheets of the first nanosheet stack with a semiconductor material to form the one or more semiconductor fins, while maintaining the sacrificial nanosheets of the second nanosheet stack.

5. The method of claim 3, further comprising depositing a high-k dielectric layer on the one or more semiconductor fins and the one or more semiconductor nanosheets after removing the oxide layer from the one or more semiconductor nanosheets.

6. The method of claim 5, wherein the oxide layer is interposed between the one or more semiconductor fins and the high-k dielectric layer.

7. The method of claim 6, wherein the high-k dielectric layer included in the FinFET is formed directly on the oxide layer, and the high-k dielectric layer included in the nanosheet transistor is formed directly on the one or more semiconductor nanosheets.

8. A method of fabricating a hybrid transistor device, the method comprising:
designating on a substrate a first region and a second region separated from the first region by distance to define a space therebetween;
forming on the first region a fin field-effect transistors (FinFET) including a gate dielectric; and
forming on the second region a nanosheet transistor excluding a gate dielectric.

9. The method of claim 8, further comprising:
forming one or more semiconductor fins in the first region;
forming one or more semiconductor nanosheets in the second region;
forming an oxide layer on the one or more semiconductor fins and the one or more semiconductor nanosheets; and
removing the oxide layer from the one or more semiconductor nanosheets while maintaining the oxide layer on the one or more semiconductor fins to form the gate dielectric of the FinFet.

10. The method of claim 9, wherein forming the one or more semiconductor fins comprises:
forming a first nanosheet stack in the first region, the first nanosheet stack including an alternating arrangement of sacrificial nanosheets and active nanosheets;
forming a second nanosheet stack in the second region, the second nanosheet stack including an alternating arrangement of sacrificial nanosheets and active nanosheets; and
replacing the sacrificial nanosheets of the first nanosheet stack with a semiconductor material to form the one or more semiconductor fins, while maintaining the sacrificial nanosheets of the second nanosheet stack.

11. The method of claim 10, wherein the active sacrificial nanosheets comprise silicon germanium (SiGe) and the semiconductor material comprises silicon (Si) to form a strained hetero structure semiconductor fin.

12. The method of claim 10, further comprising depositing a high-k dielectric on the one or more semiconductor fins and the one or more semiconductor nanosheets after removing the oxide layer from the one or more semiconductor nanosheets.

13. The method of claim 12, wherein the gate dielectric is interposed between the one or more semiconductor fins and the high-k dielectric layer.

14. The method of claim 13, wherein the high-k dielectric layer included in the FinFET is formed directly on the gate dielectric, and the high-k dielectric layer included in the nanosheet transistor is formed directly on the one or more semiconductor nanosheets.

15. A semiconductor device comprising:
a substrate including a first region and a second region separated from the first region by distance to define a space therebetween;
a first semiconductor device on the first region, the first semiconductor device including a gate dielectric; and
a second semiconductor device on the second region, the second semiconductor device excluding a gate dielectric.

16. The semiconductor device of claim 15, further comprising:
an input/output (I/O) device on the first region and including the first semiconductor device; and
a logic device on the second region and including the second semiconductor device.

17. The semiconductor device of claim 16, wherein the first semiconductor device is a fin field-effect transistor (FinFET) including one or more semiconductor fins, and wherein the second semiconductor device is a nanosheet transistor including one or more semiconductor nanosheets.

18. The semiconductor device of claim 17, further comprising:
a first high-k dielectric layer formed directly on the gate dielectric such that the gate dielectric is interposed between the first high-k dielectric layer and the one or more semiconductor fins; and
a second high-k dielectric layer formed directly on the one or more semiconductor nanosheets.

19. The semiconductor fin of claim 18, wherein the semiconductor fin comprises silicon (Si) extending continuously from an upper surface of the semiconductor fin to a base of the semiconductor fin formed on an upper surface of the substrate.

20. The semiconductor fin of claim 18, wherein the semiconductor fin comprises alternating layers of silicon germanium (SiGe) and silicon (Si), the alternating layers extending continuously from an upper surface of the semiconductor fin to a base of the semiconductor fin formed on an upper surface of the substrate.
